(19) United States
(12) Patent Application Publication
(10) Pub. No.: US 2008/0169768 A1
(43) Pub. Date: Jul. 17, 2008

(54) Electronic ballast with PCB edge mounted output transformer/inductor

(76) Inventor: Kevin Yang, Palos Verdes Estates, CA (US)

Correspondence Address: LAW OFFICES OF CLEMENT CHENG, 17220 NEWHOPE STREET #127, FOUNTAIN VALLEY, CA, 92708, US

(21) Appl. No.: 11/653,645

(22) Filed: Jan. 16, 2007

(51) Int. Cl. H05B 41/02

(52) U.S. Cl. 315/276

(57) ABSTRACT

An output transformer or inductor for electronic ballast which having a number of electronic components including diodes, transistors, resistors, various type of capacitors and different transformers/inductors mounted on a top surface of a PCB (printed circuit board) within a compact housing which envelops the whole ballast assembly. The PCB (printed circuit board) configured to relocate the output-transformer or inductor to an edge of the PCB (printed circuit board) away from the rest of the electronic components. The output-transformer terminal (the transformer's bobbin) has at least two of L-shaped brackets locked to the PCB's (printed circuit board) edge at its top surface. The output-transformer is designed in a cantilevered mounting so that it is able to quickly dissipate its operational heat to the ballast compact case with less interfered by other components. It also saves the PCB (printed circuit board) material cost because it uses shorter PCB.

### BACKGROUND AND THE INVENTION

1. Field of the Invention

The present invention relates to fluorescent lamps electronic ballast assembly. More particularly, the present invention relates to an edgewise positioned output transformer on PCB (printed circuit board).

2. Discussion of Related Art

In modern life fluorescent lighting is widely used in office buildings, shopping centers, warehouses, libraries and classrooms. Due to very special operating characteristics of fluorescent lamps, each fluorescent lamp must have a ballast to make it work properly. Modern electronic ballasts comprise semiconductors, passive electronic components and transformers to convert normal power line frequencies of 50 Hz/60 Hz to high frequencies of 20 KHz to 100 KHz for use as the lamp power source. The electronic ballasts provide illumination efficiency improvement by as much as 45 percent on actual electricity savings over conventional magnetic ballasts.

Exemplary electronic ballast that can be improved by the inventive transformer may be found at U.S. Pat. No. 6,943,502 though other variations of ballast circuit may take the benefit of the present invention. Generally, an electronic ballast circuit contains an EMI (electrical-magnetic interference) filter, an AC-DC rectifier and a high frequency inverter for converting the regular 120v 60 Hz AC (alternate current) power to a high frequency (20 k Hz˜100 k Hz) and high voltage to ignite and operate one or multiple fluorescent lamp(s).

With reference to FIG. 1 the prior art ballast 10 for fluorescent lamps comprises a planar circuit board 12 having a printed circuit on its surface facing the bottom of the drawing and active and passive components surface mounted on thru-holes formed in the circuit board 10. An ordinary electronic ballast such as that shown in FIG. 1 usually has a number of electronic components mounted on the surface. The components include capacitors 13, 14 and 16, a choke coil 18, transistors 20, at least one transformer 22 and resistors 24. The components are designed mounting in the PCB (Printed Circuit Board) based on its electronic circuits' sequence.

All components such as film capacitors, inductors and transformers are mounted on the PCB (Printed Circuit Board) with the through hole configuration (as seen in FIG. 1), while small components, the SMD (surface mounting devices) are mounted below the PCB (printed circuit board). Such conventional configuration does not provide good heat dissipation for the ballast output transformer. Furthermore, the heat generated from the output transformer 30 may affect the other components and may shorten the ballast's life since the output transformer is surrounded by other electronic components FIG. 3.

### SUMMARY OF THE INVENTION

An objective of the present invention is to provide an improved output transformer assembly reconfiguration for electronics ballast. The present invention contemplates mounting a plurality of electrical components, such as variety of capacitors, transistors, diodes, and the alike on a PCB (printed circuit board) to which a detached the output transformer is connected with minimal clearance therebetween. The resulting output-transformer assembly is isolated in that it is not physically surrounded by other components in the ballast housing.

To effectively solve the space and heat problem, it would be desirable to relocate the transformer (the largest heat source of electronic ballast), at an isolated position with respect to the other electronic components. Preferably, the transformer will have direct contact between the transformer body and the ballast housing. Moving the transformer also creates extra height for the ballast housing because the output transformer is mounted above the PCB (compare H1 with H2).

The present invention is an improvement to conventional output-transformer for electronic ballast. Typical electronic ballast contains a number of electronic components including variety of capacitors, transistors, resistors, diodes and transformers mounted on a top surface of a printed circuit board within a compact housing. The transformer may be at an output side of the ballast and comprises a pair of “EE” shaped ferrite cores with a number of windings in an appropriate bobbin. The bobbin has an array of pings extending from the output transformer for providing connections with other components of the ballast; and at least four legs protruding downwardly of the transformer at corresponding thru-holes of the PCB (Printed Circuit Board) and fixed thereto by soldering as with other components. The transformer is directly confined and surrounded by the metal housing with five (5) surfaces. The printed circuit board is shorted by having its circuit trace configured to relocate the transformer to an edge of the circuit board away from the rest of the electronic components and the terminal supports come to have one of its L-shaped brackets hug the circuit board at its top surface and a side wall area and fixed thereto in a cantilevered mounting with an array of pins from the transformer make direct contact with the trace of the circuit board, whereby dissipation of heat from the operating transformer is less hindered by other components but expedited through the compact housing in closer proximity. The objects, features, and advantages of the present invention are readily apparent from the following detailed description of the best mode for carrying out the invention when taken in connection with the accompanying drawings.

### BRIEF DESCRIPTION OF THE DRAWINGS

FIG. 1 is a side elevation view of prior art electronic ballast on a PCB (printed circuit board).

FIG. 2 is a side elevation view of electronic ballast on a PCB (printed circuit board) according to one embodiment of the invention.

FIG. 3 is a perspective view of the prior art electronic ballast of FIG. 1.

FIG. 4 is a perspective view of the inventive electronic ballast of FIG. 2.

Similar reference numbers denote corresponding features throughout the attached drawings.

### DETAILED DESCRIPTION OF THE BEST MODE PREFERRED EMBODIMENT

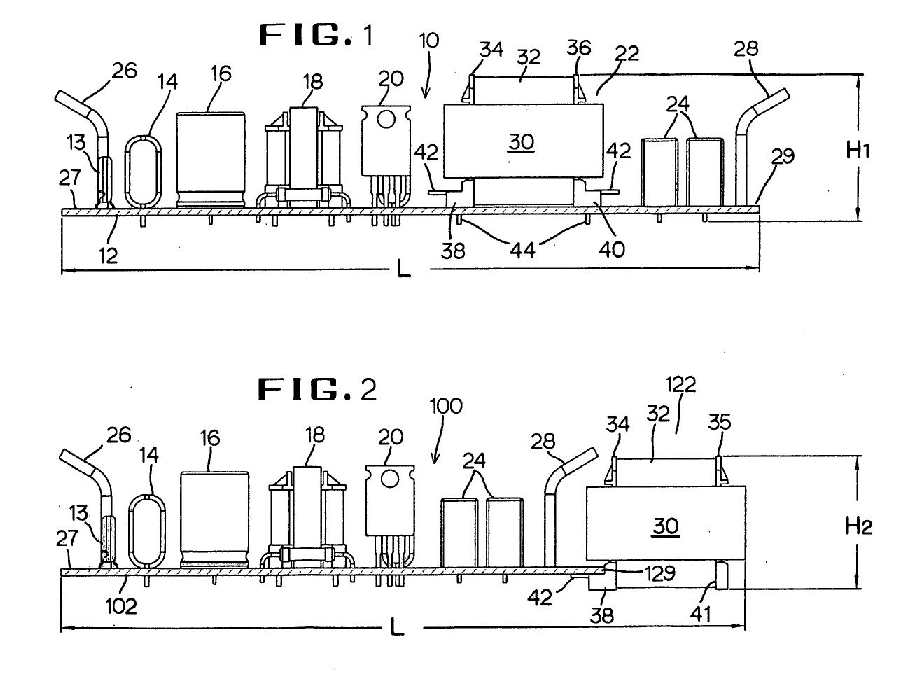

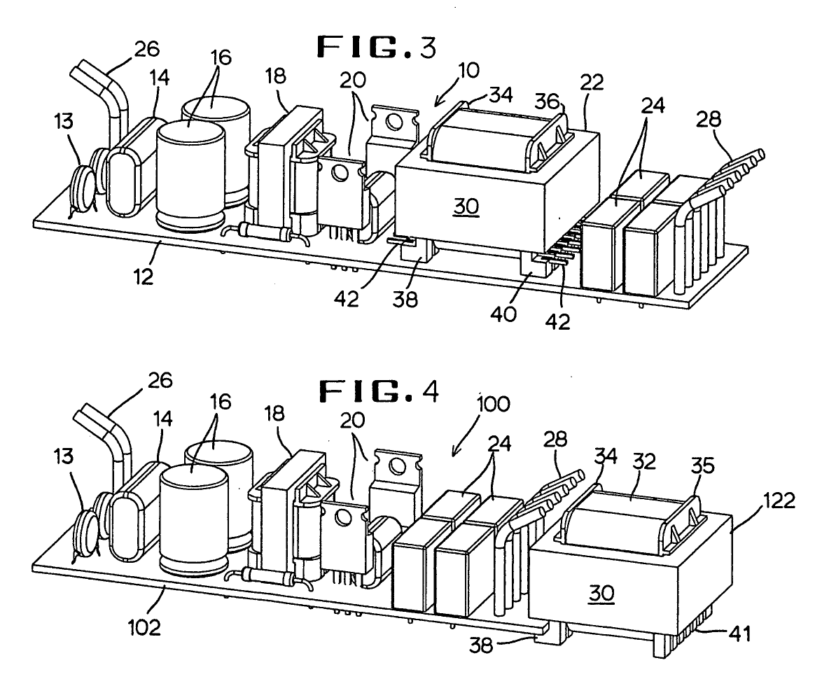

Two electronic ballasts are illustrated in the drawings as shown with their cases or enclosures removed. The old design is shown in FIG. 1, FIG. 3 and the new design is shown in FIG. 2, FIG. 4. It is well known in the art that a sheet metal enclosure consisted of an upper case and a lower case may be used to house the ballast circuitry in a dielectric sheet liner for insulation.

With reference to FIG. 1, the prior art electronic ballast PCB (printed circuit board) assembly 10 for fluorescent lamps comprises a PCB (printed circuit board) 12 having all the components mounted on the top with the thru-holes. There are some components include capacitors 13, 14, 16 and 24, an inductor 18, transistors 20, and the output transformer 22. Also inserted and soldered to the PCB (printed circuit board) are input leads wires 26 for getting the line power, and the output lead wires 28 at the opposite end 28 for supplying the high frequency current to fluorescent lamp(s).

The output-transformer 22 has two (2) “EE” shaped ferrite core 30, coupled with properly designed bobbin 34, 36, 38 and 40 with a number of windings 32. The bobbin also serves as the transformer's base or terminal 38, 40 with an array of pins 42 extending from the output transformer 22 for providing connections with other components of the ballast. There are at least four pins 44 protruding downwardly of the transformer 22 at corresponding thru-holes of the PCB (printed circuit board) 12 and fixed thereto by soldering as with other components.

In comparison, FIG. 1 and the FIG. 2 show the modified ballast assembly 100 having all the equivalent components of ballast 10 on a smaller PCB (printed circuit board) 102, which is terminated short of the full length L of the ballast 10. The length of the PCB (printed circuit board) 12 in FIG. 1 is now shortened and instead a modified transformer 122 is mounted on the edge of the circuit board 102 whereby the overall length of the circuit board 102 is reduced. The PCB (printed circuit board)'s trace may be modified at the area of the board 102 near the output edge so that it maintains the same connections with the components that changed places. The transformer 122 comprises the “EE” shaped ferrite core 30, winding 32 and the bobbin 34, 36 at one side of the transformer 122, too. The transformer's bobbin 34 has bracket 38 underneath of the ferrite core with an array of pins 42 to be soldered to the PCB (printed circuit board) soldering pads. The other terminal support 35 extends the same length as that of the support 34 but terminates at a straight end 41 without any pins.

This edgewise mounting of the transformer 122 allows more intimate connections between the transformer 122 and circuit board 102. The L-shaped bracket 38 hugs an output side edge 129 of the circuit board 102 instead of being through-hole mounted as in FIG. 1.

In size, the length L of the modified electronic ballast PCB (printed circuit board) 100 may stay the same as the conventional electronic ballast PCB (printed circuit board) assembly 10, indicated in the FIG. 1. But the PCB (printed circuit board) assembly's profile is reduced from the PCB (printed circuit board) assembly 10 H1 to the PCB (printed circuit board) assembly 100 H2 as FIG. 2 (the actual dimension of the illustrated figure is reduced from previous' 1.1″ H1 to 0.9″ H2, and it is about 20% reduction). The reduction allows the casing to fit into locations that would not otherwise be available.

Therefore, the resultant ballast may be made ever more compact than before to produce a lighter, lower profile and less cost of fixture for fluorescent lamp(s). The cantilevered output-transformer 122 shows in FIG. 2 is located near an end wall of the ballast case and physically distanced from the rest of other electronic components so that the heat generated from the output-transformer 122 itself can be quickly and effectively dissipated through its five (5) sides of direct adjacent ballast metal case and thereby prolong the electronic ballast operation life according to the well known Murphy's law (every 10 degree C. temperature reduction should be able to double the electronic products' operation life). The end wall is typically made of a metal housing, such as steel or aluminum. The housing can dissipate heat and function as a big heat sink. The transformer is shown as a substantially rectangular element, and has several sidewalls that can touch the metal housing. The sidewalls of the housing can touch directly or via thermal grease or thermal tape, commonly available for thermally connecting the elements to allow conductivity. Thus, touching in this description includes touching via thermal grease, thermal tape or a conductor such as a properly shaped metal member.

Therefore, while the presently preferred configuration of output-transformer of the electronic ballast has been shown and described, it is to be understood that the present invention is not limited to the sole embodiment describe above, but encompasses any and all embodiments within the scope of the following claims. The housing that envelops the ballast assembly and printed circuit board can be in a variety of shapes. The printed circuit board can be in a variety of shapes.

1. An electronic ballast assembly comprising:
a. a printed circuit board having circuit trace;
b. a plurality of electronic components chosen from the group of: capacitors, transistors, resistors and diodes, wherein the plurality of electronic components are mounted on a surface of the printed circuit board;
c. a housing that envelops the ballast assembly; and
d. an output-transformer mounted on an edge of the printed circuit board, wherein the plurality of electronic components and the transformer form an electric circuit configured to provide electricity for one or more florescent lamps.

2. The electronic ballast assembly of claim 1, wherein the output-transformer has, on a side, terminal connecting pins directly soldered to the back surface of the printed circuit board for providing connections with the plurality of electronic components.

3. The electronic ballast assembly of claim 1, wherein the printed circuit board has its circuit trace configured to locate the output-transformer to an edge of the printed circuit board.

4. The electronic ballast assembly of claim 1, wherein the transformer has an L-shaped bracket that contacts the printed circuit board at a bracket top surface in a cantilevered mounting with an array of pins from the transformer making direct contact with a trace of the printed circuit board.

5. The electronic ballast assembly of claim 1, wherein one side of a body of the transformer is connected with the printed circuit board end, wherein five other sides of the body of the transformer are directly adjacent to the ballast housing.

6. The electronic ballast assembly of claim 1, wherein a transformer side wall of a core of the transformer defines a longitudinal end of the electronic ballast.

7. An electronic ballast assembly with optimized transformer comprising:
a. a number of electronic components mounted on a top surface of a circuit board printed at its surface with circuit traces including a compact housing which envelops the transformer assembly, wherein the transformer is at an output side of the ballast and comprises a pair of “E-shaped” ferrite cores;
b. a pair of terminal supports made of dielectric material, the supports extending through the core laminations down to the bottom thereof and being terminated by L-shaped brackets surface mounted on the surface of the circuit board;
c. the printed circuit board having its circuit trace configured to relocate the transformer to an edge of the circuit board away from the rest of the electronic components and
d. the terminal supports of the transformer having one of its L-shaped brackets hug the circuit board at its top surface and a side wall area and fixed thereto in a cantilevered mounting with an array of pins from the transformer making direct contact with the trace of the circuit board.

8. The electronic ballast assembly of claim 7, wherein the transformer has, on a side, terminal connecting pins directly soldered to the back surface of the printed circuit board for providing connections with the plurality of electronic components.

9. The electronic ballast assembly of claim 7, wherein the printed circuit board has its circuit trace configured to locate the output-transformer to an edge of the printed circuit board.

10. The electronic ballast assembly of claim 7, wherein the transformer has an L-shaped bracket that contacts the printed circuit board at a bracket top surface in a cantilevered mounting with an array of pins from the transformer making direct contact with a trace of the printed circuit board.

11. The electronic ballast assembly of claim 7, wherein one side of a body of the transformer is connected with the printed circuit board end, wherein five other sides of the body of the transformer are directly adjacent to the ballast housing.

12. The electronic ballast assembly of claim 7, wherein a transformer side wall of a core of the transformer defines a longitudinal end of the electronic ballast.

13. An electronic ballast assembly comprising:
a. a printed circuit board having circuit trace, a printed circuit board top surface, a printed circuit board bottom surface, a printed circuit board length and a printed circuit board width, wherein the printed circuit board length is greater than the printed circuit board width;
b. a plurality of electronic components chosen from the group of: capacitors, transistors, resistors and diodes, wherein the plurality of electronic components are mounted on a top surface of the printed circuit board;
c. a metal housing that envelops the ballast assembly, the metal housing conforming to the shape of the printed circuit board, wherein the length of the printed circuit board defines two opposite ends; and
d. a transformer mounted on an edge one of the two opposite ends of the printed circuit board, wherein the plurality of electronic components and the transformer form an electric circuit configured to provide electricity for florescent lighting.

14. The electronic ballast assembly of claim 13, wherein the transformer has, on a side, terminal connecting pins directly soldered to the back surface of the printed circuit board for providing connections with the plurality of electronic components.

15. The electronic ballast assembly of claim 13, wherein the printed circuit board has its circuit trace configured to locate the transformer to an edge of the printed circuit board.

16. The electronic ballast assembly of claim 13, wherein the transformer has an L-shaped bracket that contacts the printed circuit board at a bracket top surface in a cantilevered mounting with an array of pins from the transformer making direct contact with a trace of the printed circuit board.

17. The electronic ballast assembly of claim 13, wherein one side of a body of the transformer is connected with the printed circuit board end, wherein five other sides of the body of the transformer are directly adjacent to the ballast housing.

18. The electronic ballast assembly of claim 13, wherein a transformer side wall of a core of the transformer defines a longitudinal end of the electronic ballast.
